(19) United States
(12) Patent Application Publication
(10) Pub. No.: US 2009/0203285 A1
(43) Pub. Date: Aug. 13, 2009

(54) METHOD FOR PRODUCING LIGHT-EMITTING DEVICE

(75) Inventor: Hidekazu KOBAYASHI, Azumino-shi (JP)

Correspondence Address: OLIFF & BERRIDGE, PLC, P.O. BOX 320850, ALEXANDRIA, VA, 22320-4850, US

(73) Assignee: SEIKO EPSON CORPORATION, Tokyo (JP)

(21) Appl. No.: 12/359,680

(22) Filed: Jan. 26, 2009

(30) Foreign Application Priority Data
Feb. 7, 2008 (JP) 2008-027300

(51) Int. Cl. H01J 9/00

(52) U.S. Cl. 445/58

(57) ABSTRACT

A method for producing a light-emitting device including an acceptor substrate as a base includes ejecting functional liquids containing organic functional materials into target sites on a donor substrate; removing a solvent from the functional liquids to form organic functional layers containing the organic functional materials in the target sites; disposing the donor substrate such that the organic functional layers are positioned opposite the acceptor substrate; and transferring the organic functional layers onto the acceptor substrate by heating the organic functional layers under a reduced pressure with the donor substrate disposed opposite the acceptor substrate.

### BACKGROUND

1. Technical Field

The present invention relates to methods for producing light-emitting devices.

2. Related Art

In an example of a known light-emitting device including light-emitting elements, light-emitting functional layers that emit light of different colors are formed in the light-emitting elements. The light-emitting functional layers can be formed of, for example, organic electroluminescent (EL) materials. Known methods for forming light-emitting functional layers that emit light of different colors in light-emitting elements include one in which light-emitting materials are deposited at target positions through a mask and one in which functional liquids containing light-emitting materials are ejected at target positions using a droplet-ejecting apparatus before being dried to form light-emitting functional layers.

The method of forming light-emitting functional layers by vapor deposition has the problem of low utilization efficiency of materials. As an approach to solving this problem, JP-A-2006-344459 discloses a method in which a monochrome light-emitting material is transferred from a donor substrate (transfer substrate) onto an acceptor substrate through vapor deposition by depositing the light-emitting material on the donor substrate, stacking the donor substrate on the acceptor substrate, and heating the donor substrate using a laser,

This method, however, has a problem in that it requires donor substrates on which light-emitting materials of different colors are deposited. Another problem is the difficulty in increasing yield because the donor substrates must be replaced for sequential transfer, which demands high precision in alignment, laser focusing, and laser scanning.

### SUMMARY

A method according to an aspect of the invention for producing a light-emitting device including an acceptor substrate as a base includes ejecting functional liquids containing organic functional materials into target sites on a donor substrate; removing a solvent from the functional liquids to form organic functional layers containing the organic functional materials in the target sites; disposing the donor substrate such that the organic functional layers are positioned opposite the acceptor substrate; and transferring the organic functional layers onto the acceptor substrate by heating the organic functional layers under a reduced pressure with the donor substrate disposed opposite the acceptor substrate.

According to this method, organic functional layers with different properties can be formed in the target sites on the donor substrate and then transferred onto the acceptor substrate, which serves as the base of the lights emitting device, through vapor deposition. This allows different types of organic functional layers to be simultaneously transferred from the single donor substrate, thus reducing process time. In addition, even if the functional liquids contain impurities, the impurity concentration of the organic functional layers can be reduced after the transfer of the organic functional layers.

In the above method for producing the light-emitting device, the organic functional layers may be transferred by irradiating the side of the donor substrate facing away from the organic functional layers with radiant rays.

According to this method, the organic functional layers can be transferred onto the acceptor substrate by heating the organic functional layers with the energy of the radiant rays. The radiant rays do not have to be focused or shielded to irradiate the particular target sites; they may be simultaneously applied to a region covering many target sites. This simplifies the optical system of the production apparatus used and reduces the process time.

In the above method for producing the light-emitting device, the bottoms of the target sites may be defined by a photothermal conversion layer formed on a surface of the donor substrate, and the organic functional layers may be transferred by irradiating the photothermal conversion layer with the radiant rays.

According to this method, the photothermal conversion layer can convert the energy of the radiant rays into heat. The organic functional layers, heated by the heat generated from the photothermal conversion layer, can be efficiently transferred onto the acceptor substrate.

In the above method for producing the light-emitting device, the organic functional layers may be transferred by heating the donor substrate.

According to this method, the organic functional layers on the donor substrate can be simultaneously heated and transferred onto the acceptor substrate. This reduces the process time.

In the above method for producing the light-emitting device, the target sites may be recesses whose sides are defined by a partition formed on the donor substrate.

According to this method, functional liquids with different properties can be ejected into the target sites. In addition, the partition partitions the target sites to prevent the functional liquids provided in the target sites from being mixed between the adjacent target sites.

In the above method for producing the light-emitting device, a surface of the donor substrate may have a liquids repellent region and lyophilic regions surrounded by the liquid-repellent region, and the target sites may be the lyophilic regions on the surface of the donor substrate.

According to this method, functional liquids with different properties can be ejected into the target sites. In addition, the functional liquids provided in the target sites can be prevented from being mixed between the adjacent target sites.

In the above method for producing the light-emitting device, the light-emitting device may include light-emitting elements that each emit light of one of different colors, the target sites may be arranged so as to have a mirrors image relationship with the light-emitting elements, and the donor substrate may be disposed such that the target sites overlap the corresponding light-emitting elements in plan view.

According to this method, the organic functional layers can be formed at the positions on the donor substrate that correspond to the light-emitting elements of the light-emitting device and can be transferred therefrom. This allows organic functional layers with predetermined properties to be provided in the light-emitting elements of the light-emitting device.

In the above method for producing the light-emitting device, the light-emitting elements may each correspond to one of the different colors, and the functional liquids ejected into the target sites may contain different organic functional materials for the individual colors of the light-emitting elements to which the target sites correspond.

According to this method, the single donor substrate can be used to produce a light-emitting device capable of color light emission.

In the above method for producing the light-emitting device, the light-emitting elements may each correspond to one of the different colors, and the functional liquids ejected into the target sites may contain organic functional materials that emit light of the colors of the light-emitting elements to which the target sites correspond.

According to this method, the single donor substrate can be used to produce a light-emitting device capable of color light emission.

### BRIEF DESCRIPTION OF THE DRAWINGS

The invention will be described with reference to the accompanying drawings, wherein like numbers reference like elements.

FIG. 1 is a circuit diagram showing the overall configuration of an organic EL device serving as a light-emitting device.

FIG. 2 is an enlarged plan view of the organic EL device.

FIG. 3 is a schematic sectional view of the organic EL device.

FIG. 4 is a flowchart of a method for producing the organic EL device according to a first embodiment.

FIGS. 5A to 5C are sectional views illustrating Steps S11 to S13 in FIG. 4.

FIGS. 6A to 6D are sectional views illustrating Steps S21 to S23 in FIG. 4.

FIGS. 7A to 7D are sectional views illustrating Steps S14 to S16 in FIG. 4.

FIG. 8 is a perspective view illustrating laser irradiation in Step S14.

FIG. 9 is a flowchart of a method for producing the organic EL device according to a second embodiment.

FIGS. 10A to 10D are sectional views illustrating Steps P21 to P23 in FIG. 9.

FIGS. 11A to 11C are sectional views illustrating Steps P14 to P16 in FIG. 9.

FIG. 12 is a schematic sectional view of a bottom-emission organic EL device.

FIG. 13 is a perspective view of a cellular phone serving as an electronic apparatus.

### DESCRIPTION OF EXEMPLARY EMBODIMENTS

Light-emitting devices and methods for producing light-emitting devices according to embodiments of the invention will now be described with reference to the drawings, where the dimensions and dimensional ratios of individual components are appropriately varied from their actual ones so that they are large enough to be visible in the drawings.

### First Embodiment

### A. Light-Emitting Device

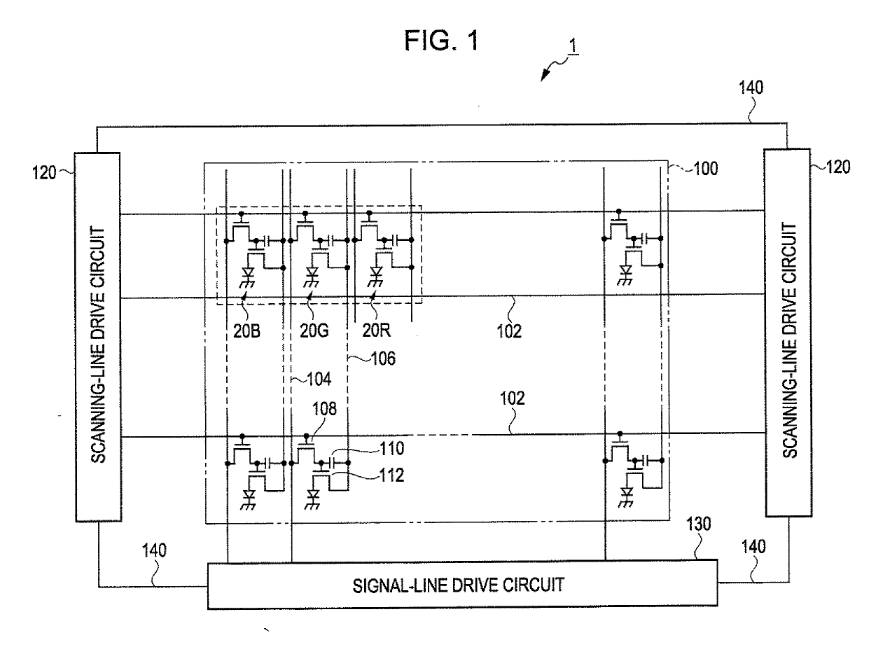

FIG. 1 is a circuit diagram showing the overall configuration of an organic EL device 1 serving as a light-emitting device. The organic EL device 1 includes light-emitting elements 20R that emit red light, light-emitting elements 20G that emit green light, and light-emitting elements 20B that emit blue light (they are hereinafter also simply referred to as the light-emitting elements 20 unless the colors of light emitted are specified). The organic EL device 1 is an active-matrix device that separately controls the emission of light from the light-emitting elements 20 to create an image in a display region 100 including the numerous light-emitting elements 20. Scanning lines 102, signal lines 104 perpendicular to the scanning lines 102, and power supply lines 106 parallel to the signal lines 104 are arranged in the display region 100. Square regions surrounded by the scanning lines 102, the signal lines 104, and the power supply lines 106 are hereinafter referred to as pixel regions.

The individual pixel regions include switching thins film transistors (TFTs) 108 whose gate electrodes are supplied with scanning signals from the scanning lines 102, hold capacitors 110 that hold pixel signals supplied from the signal lines 104 via the switching TFTs 108, drive TFTs 112 whose gate electrodes are supplied with the pixel signals held by the hold capacitors 110, and the light-emitting elements 20, into which a drive current flows from the power supply lines 106 via the drive TFTS 112. The light-emitting elements 20 emit light with the luminance corresponding to the current flowing therethrough.

The display region 100 is surrounded by scanning-line drive circuits 120 and a signal-line drive circuit 130. The scanning-line drive circuits 120 sequentially supply the scanning lines 102 with scanning signals in response to various signals supplied from external circuitry (not shown). The signal-line drive circuit 130 supplies the signal lines 104 with pixel signals. The power supply lines 106 are supplied with a pixel-driving current from external circuitry (not shown). The scanning-line drive circuits 120 and the signal-line drive circuit 130 are synchronized in operation with each other by synchronization signals supplied from external circuitry via synchronization signal lines 140.

When the scanning lines 102 are driven to switch the switching TFTs 108 on, the potentials of the signal lines 104 at that time are held by the hold capacitors 110, whose states determine the levels of the drive TFTs 112. A drive current then flows from the power supply lines 106 into the light-emitting elements 20 via the drive TFTs 112. The light-emitting elements 20 emit light in response to the drive current. The individual light-emitting elements 20 are controlled independently; a color image is created in the display region 100 by adjusting the luminances of red, green, and blue light emitted from the respective light-emitting elements 20R, 20G, and 20B depending on the drive current. The order of arrangement of the light-emitting elements 20R, 20G, and 20B is not limited to that shown in FIG. 1; for example, they may be arranged in the order of the light-emitting elements 20R, 20B, and 20G. In addition, the light-emitting elements 20R, 20G, and 20B do not have to have the same size in a plane.

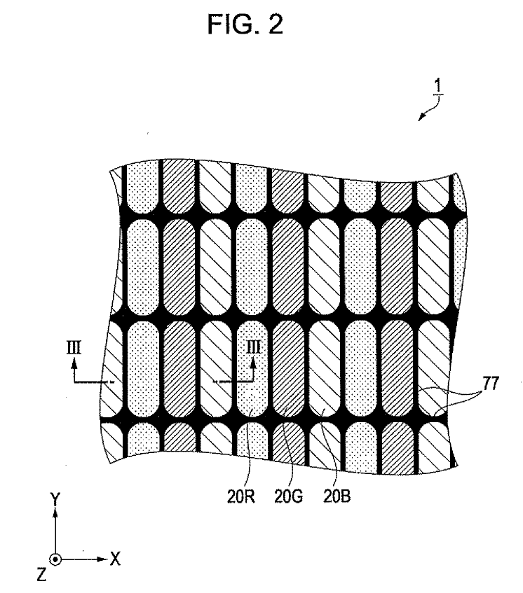

FIG. 2 is an enlarged plan view of the organic EL device 1. The light-emitting elements 20, as the figure shows, are arranged in a matrix in plan view, and those arranged in each column have the same color. That is, the light-emitting elements 20 are arranged in stripes of corresponding colors. A partition 77 is disposed in a region between the adjacent light-emitting elements 20. In other words, each region surrounded by the partition 77 is occupied by one light-emitting element 20 in plan view. In addition, each group of three adjacent light-emitting elements 20R, 20G, and 20B arranged in the row direction constitutes a minimum display unit (i.e., a pixel). In this specification, the row direction in which the light-emitting elements 20 are arranged is referred to as the X direction, and the column direction is referred to as the Y direction.

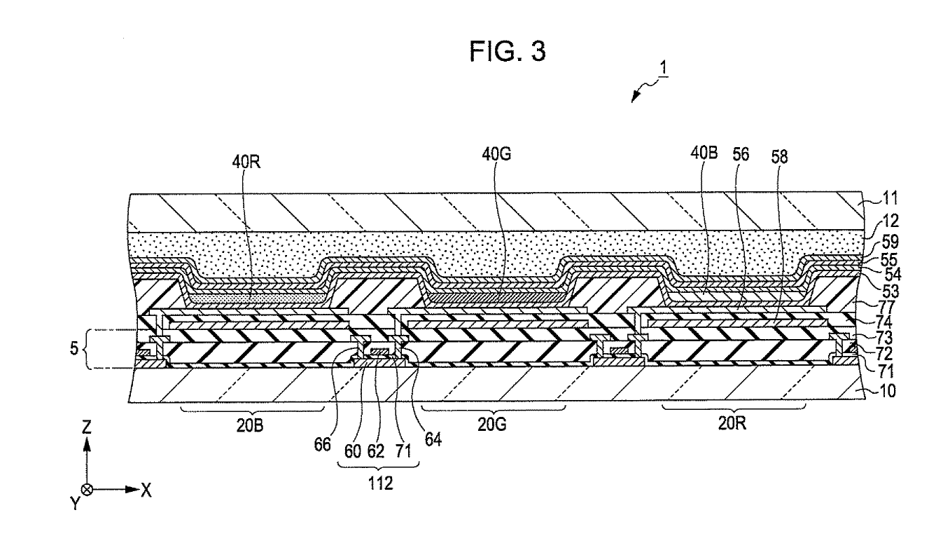

FIG. 3 is a schematic sectional view, taken along line III-III of FIG. 2, of the organic EL device 1. The organic EL device 1 is a top-emission organic EL device that emits light in the +Z direction, that is, from a counter substrate 11; therefore, the viewer views the organic EL device 1 from the counter substrate 11 side.

The organic EL device 1 is configured using an acceptor substrate 10 as a base. The acceptor substrate 10 is formed of a material such as glass or quartz. The drive TFTs 112 are disposed on the acceptor substrate 10, each including a channel region 60 formed of a polysilicon layer, a gate insulating film 71 formed of a material such as silicon oxynitride, and a gate electrode 62 formed of a material such as polysilicon or aluminum (Al). Note that the switching TFTs 108 are omitted in FIG. 3. A first interlayer insulating layer 72 formed of a material such as silicon oxynitride is disposed over the drive TFTs 112. With part of the first interlayer insulating layer 72 selectively removed, drain electrodes 64 and source electrodes 66 are formed so as to be electrically connected to the channel regions 60. The acceptor substrate 10 is a substrate on which various elements such as the TFTs and the light-emitting elements 20 are disposed. Although this type of substrate is generally referred to as an element substrate, the term “acceptor substrate 10” is used in this specification, reflecting the features of the production process described later.

A second interlayer insulating layer 73 formed of a material such as silicon oxynitride is disposed over the drain electrodes 64 and the source electrodes 66. Reflective layers 58 formed of a material such as aluminum are disposed on the second interlayer insulating layer 73. Anodes 56 serving as pixel electrodes are disposed above the reflective layers 58 with a third interlayer insulating layer 74, formed of a material such as silicon oxynitride, disposed therebetween. The anodes 56 are formed by processing a thin film of indium tin oxide (ITO), a transparent conductive material, into an island-like pattern corresponding to the individual light-emitting elements 20. The anodes 56 are electrically connected to the drain electrodes 64 via contact holes provided above the drain electrode 64 so as to extend through the second interlayer insulating layer 73 and the third interlayer insulating layer 74. The anodes 56 may be formed of a transparent conductive material other than ITO, such as indium zinc oxide. The reflective layers 58 and the anodes 56 may have a thickness of, for example, about 100 nm.

The partition 77 is disposed on the third interlayer insulating layer 74 and the anodes 56. The partition 77 is formed by patterning a layer of an organic insulating material, such as polyimide, or a layer of an inorganic insulating material. The patterning is performed so as to remove regions overlapping the anodes 56 and the reflective layers 58 in plan view, that is, so as to expose the anodes 56. The partition 77 thus defines recesses at the positions corresponding to the light-emitting elements 20. In addition, a hole-injecting layer 53 is disposed over the anodes 56 and the partition 77.

Light-emitting functional layers 40 of the colors corresponding to the light-emitting elements 20 are disposed on the hole-injecting layer 53, specifically, in the recesses defined by the partition 77. That is, the light-emitting elements 20R, 20G, and 20B include the light-emitting functional layers 40R, 40G, and 40B, respectively, which emit red, green, and blue light (they are hereinafter also simply referred to as the light-emitting functional layers 40 unless the corresponding colors are specified). The light-emitting functional layers 40R, 40G, and 40B contain low-molecular-weight light-emitting materials. For example, the light-emitting functional layers 40R can be formed of a light-emitting material containing BH215 (manufactured by Idemitsu Kosan Co., Ltd.) as a host material and RD001 (manufactured by Idemitsu Kosan Co., Ltd.) as a dopant. In addition, the light-emitting functional layers 40G can be formed of a light-emitting material containing BH215 (manufactured by Idemitsu Kosan Co., Ltd.) as a host material and GD206 (manufactured by Idemitsu Kosan Co., Ltd.) as a dopant. Furthermore, the light-emitting functional layers 40B can be formed of a light-emitting material containing BH215 (manufactured by Idemitsu Kosan Co., Ltd.) as a host material and BD102 (manufactured by Idemitsu Kosan Co., Ltd.) as a dopant.

An electron-injecting layer 54, a cathode 55, and a sealing layer 59 are sequentially stacked on the light-emitting functional layers 40 and the hole-injecting layer 53. The electron-injecting layer 54 has a thickness of about 1 nm and is formed of lithium fluoride (LiF), functioning to improve the efficiency of electron injection from the cathode 55 and therefore light-emission efficiency. The cathode 55 is preferably formed of a metal with a work function of 4.2 eV or less or an alkali metal or alkaline earth metal with a work function of 3.5 eV or less. In this embodiment, the cathode 55 is formed of magnesium-silver (Mg—Ag) alloy. Having a thickness of about 10 nm, the cathode 55 is transflective, that is, reflects about 50% of incident light and transmits about 50% of it. The sealing layer 59 is preferably formed of a transparent material with superior gas-barrier properties. In this embodiment, the sealing layer 59 is formed of a silicon oxynitride (SiOₓN_{y}) film with a thickness of about 200 nm. Of the components of the light-emitting elements 20, the layers from the hole-injecting layer 53 to the electron-injecting layer 54 correspond to organic functional layers.

The counter substrate 11 is bonded to the sealing layer 59 with an adhesive layer 12. The adhesive layer 12 and the counter substrate 11 function to protect the light-emitting elements 20 from, for example, moisture, gas, and impact. Color filters may be provided on the side of the counter substrate 11 facing the acceptor substrate 10. More specifically, red, green, and blue color filters may be provided in regions overlapping the light-emitting elements 20R, 20G, and 20S, respectively, in plan view. Such color filters improve the color purity of light output from the organic EL device 1 and reduce reflection of external light.

In the organic EL device 1 thus configured, the drive current supplied via the drive TFTs 112 flows between the anodes 56 and the cathode 55. That is, the drive current is supplied to the organic functional layers, including the light-emitting functional layers 40. The light-emitting functional layers 40, which are layers of organic light-emitting materials that cause electroluminescence, emit light with the luminance corresponding to the current flowing therethrough. More specifically, the voltage applied between the anodes 56 and the cathode 55 forces holes to be injected from the hole-injecting layer 53 into the light-emitting functional layers 40 and electrons to be injected from the electron-injecting layer 54 into the light-emitting functional layers 40. These carriers recombine together in the light-emitting functional layers 40, thus emitting light.

Some of the light emitted from the light-emitting functional layers 40 passes through the cathode 55 directly, while other light passes through the cathode 55 after being reflected from the reflective layers 58. After the light emitted from the light-emitting functional layers 40 passes through the cathode 55 in either way, it passes through the sealing layer 59, the adhesive layer 12, and the counter substrate 11 sequentially, finally exiting the organic EL device 1.

B. Method for Producing Light-Emitting Device

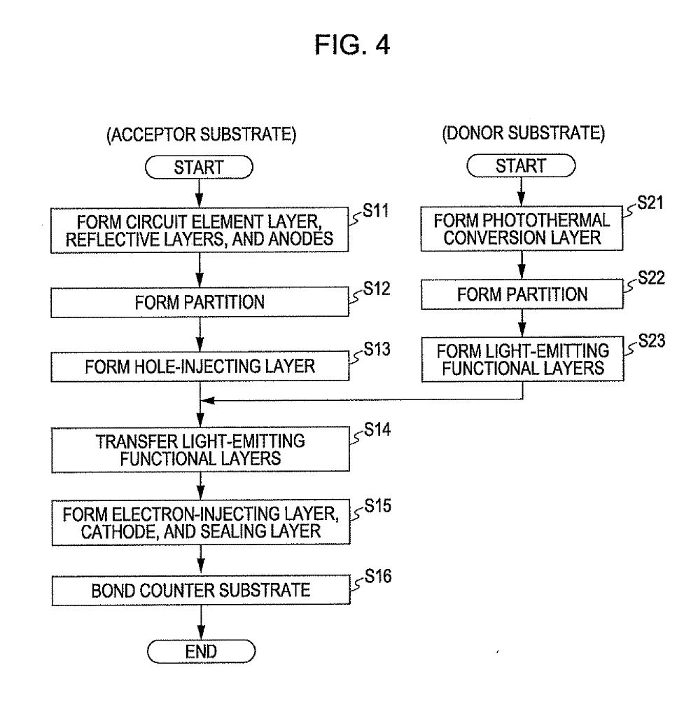

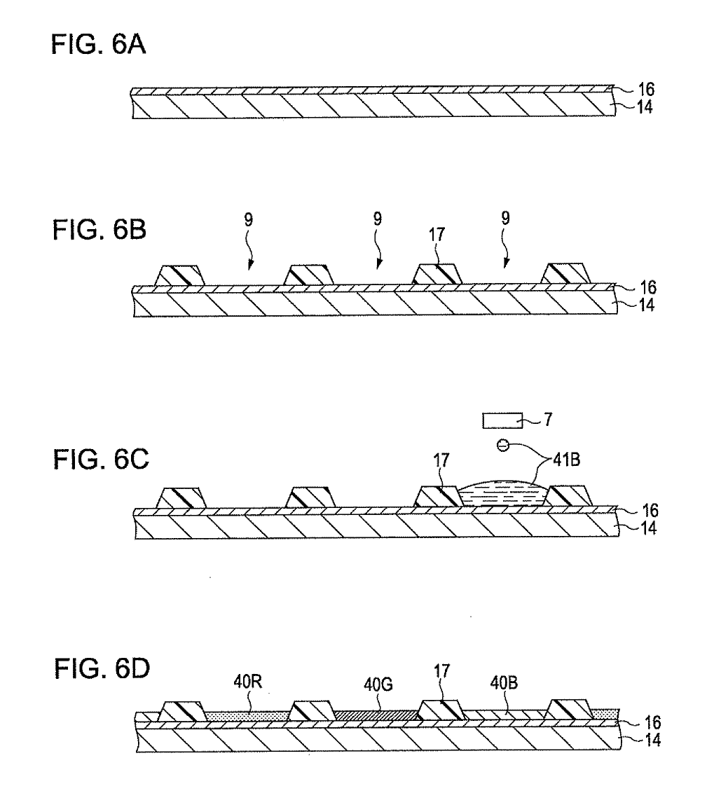

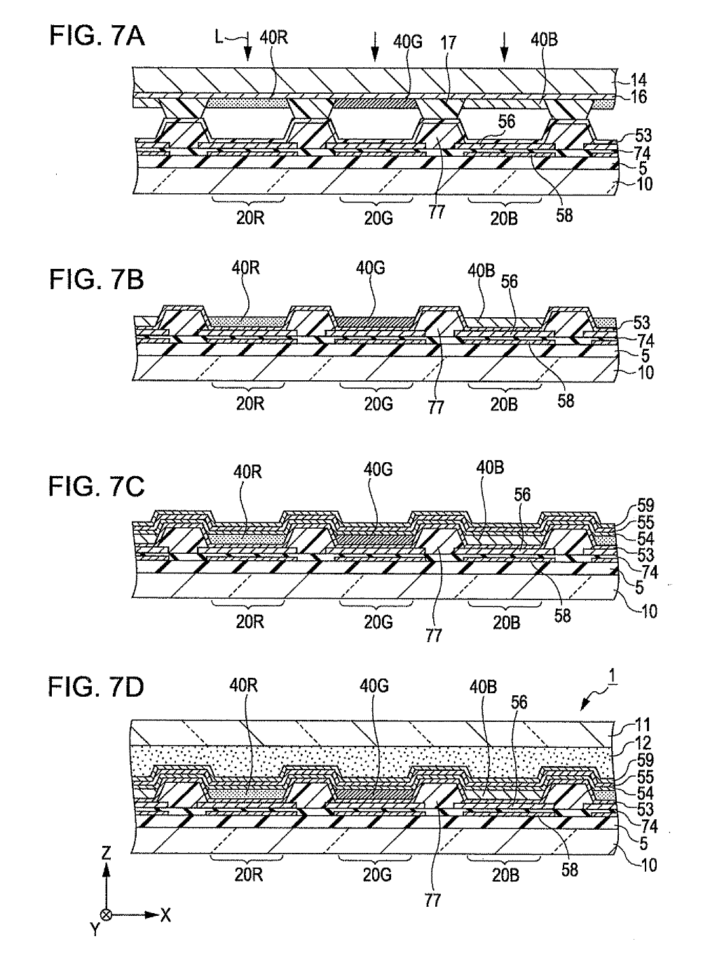

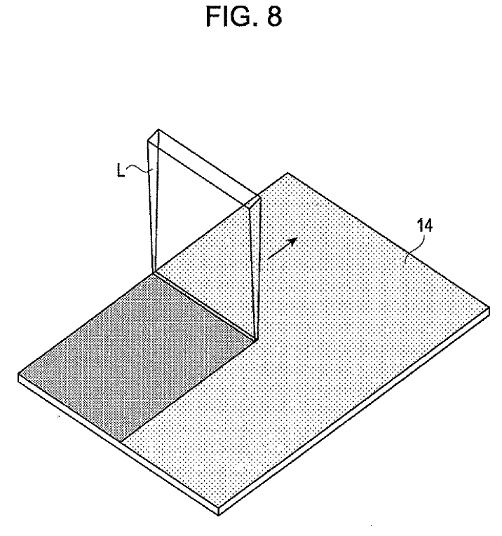

Next, a method for producing the organic EL device 1 as a light-emitting device will be described with reference to FIGS. 4 to 8. FIG. 4 is a flowchart of the method for producing the organic EL device 1 according to the first embodiment. FIGS., 5A to 5C are sectional views illustrating Steps S11 to S13 in FIG. 4. FIGS. 6A to 6D are sectional views illustrating Steps S21 to S23 in FIG. 4. FIGS. 7A to 7D are sectional views illustrating Steps S14 to S16 in FIG. 4. FIG. 8 is a perspective view illustrating laser irradiation in Step S14. The method for producing the organic EL device 1 will now be described along the flowchart of FIG. 4.

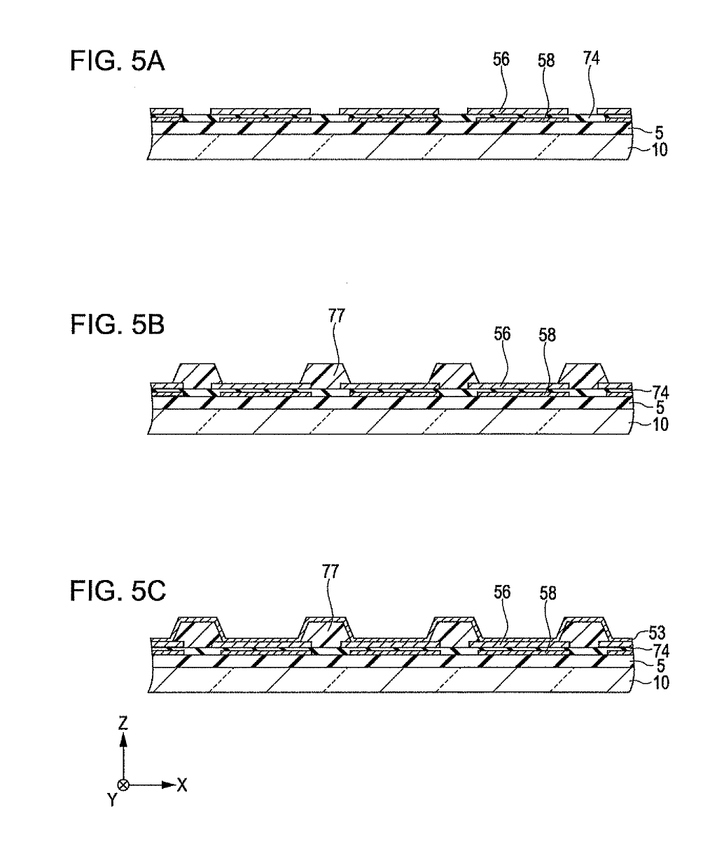

In Step S11, a circuit element layer 5, the reflective layers 58, and the anodes 56 are formed on the acceptor substrate 10 (see FIG. 5A). Of the components on the acceptor substrate 10 in FIG. 3, the circuit element layer 5 refers to the layers from the layers including the channel regions 60 to the second interlayer insulating layer 73. The third interlayer insulating layer 74, as described above, is formed between the reflective layers 58 and the anodes 56. The anodes 56 are formed in an island-like pattern corresponding to the individual light-emitting elements 20. Step S11 can be performed by various film-forming and patterning processes including plasma-enhanced chemical vapor deposition (CVD), sputtering, and various etching processes.

In Step S12, the partition 77 is formed in a site including a region between the adjacent anodes 56 (see FIG. 5B). Step S12 includes, for example, a substep of forming a layer of an organic material, such as polyimide, over substantially the entire surface of the acceptor substrate 10 and a substep of patterning the organic material layer by photolithography.

In Step S13, the hole-injecting layer 53 is formed over substantially the entire surface of the acceptor substrate 10 (see FIG. 5C). Step S13 can be performed by various film-forming processes including spin coating, slit coating, and vapor deposition. After Step S13, recesses are formed by the partition 77 at the positions corresponding to the light-emitting elements 20 on the acceptor substrate 10.

Step S14 is preceded by Steps S21 to S23 because a donor substrate 14 to be produced in Step S23 is used in Step S14.

In Step S21, a photothermal conversion layer 16 is formed over substantially the entire surface of the donor substrate 14 (see FIG. 6A). The donor substrate 14 may be formed of either glass or a resin such as polyimide. The photothermal conversion layer 16, a layer for converting optical energy obtained by absorbing light into thermal energy, may be formed of a material, such as carbon or titanium oxide, that efficiently absorbs light, such as infrared light, to generate heat.

In Step S22, a partition 17 is formed on the photothermal conversion layer 16 (see FIG. 6B). The partition 17 is preferably formed of a heat-resistant resin such as polyimide. Step S22 includes, for example, a substep of forming a layer of the resin over substantially the entire surface of the photothermal conversion layer 16 and a substep of patterning the resin layer by photolithography. After the patterning, the surface of the partition 17 is selectively made liquid-repellent. For example, the entire surface of the donor substrate 14 is made lyophilic by oxygen plasma treatment before only the surface of the partition 17 is made liquid-repellent by CF₄ plasma treatment. After Step S22, recesses are formed on the donor substrate 14, with their bottoms defined by the photothermal conversion layer 16 and their sides defined by the partition 17. These recesses are hereinafter also referred to as target sites 9.

The target sites 9 are arranged such that they have a mirror-image relationship in arrangement with the light-emitting elements 20 on the acceptor substrate 10. That is, the target sites 9 are formed in the matrix corresponding to that of the light-emitting elements 20 such that the target sites 9 have one-to-one correspondence in arrangement with the light-emitting elements 20 when the donor substrate 14 is stacked on the acceptor substrate 10 with the target sites 9 positioned opposite the light-emitting elements 20.

In Step S23, the light-emitting functional layers 40 are formed in the target sites 9 by droplet ejection (see FIGS. 6C and 6D). Step S23 includes a substep of ejecting functional liquids 41 containing light-emitting materials as organic functional materials into the target sites 9 on the donor substrate 14 (Substep A) and a substep of removing a solvent from the functional liquids 41 to form the light-emitting functional layers 40 in the target sites 9 as organic functional layers containing light-emitting materials (Substep B).

of these, Substep A will be described. First, the functional liquids 41 are prepared, containing organic functional materials. More specifically, a functional liquid 41R containing a red light-emitting material as an organic functional material, a functional liquid 41G containing a green light-emitting material as an organic functional material, and a functional liquid 41B containing a blue light-emitting material as an organic functional material are prepared (they are hereinafter also simply referred to as the functional liquids 41 unless the corresponding colors are specified). The functional liquid 41R can be a 2% solution of a mixture of the light-emitting-layer host material BH215 (manufactured by Idemitsu Kosan Co., Ltd.) and the red light-emitting dopant RD001 (manufactured by Idemitsu Kosan Co., Ltd.) in a solvent. The functional liquid 41G can be a 2% solution of a mixture of the light-emitting-layer host material BH215 (manufactured by Idemitsu Kosan Co., Ltd.) and the green light-emitting dopant GD206 (manufactured by Idemitsu Kosan Co., Ltd.) in a solvent. The functional liquid 41B can be a 2% solution of a mixture of the light-emitting-layer host material BH215 (manufactured by Idemitsu Kosan Co., Ltd.) and the blue light-emitting dopant BD102 (manufactured by Idemitsu Kosan Co., Ltd.) in a solvent. The dopant-to-host mixing ratio can be several percent to about ten percent. The solvent used for the functional liquids 41 can be, for example, toluene or xylene.

The functional liquids 41 thus prepared are ejected from a droplet-ejecting head 7 of a droplet-ejecting apparatus into the target sites 9 (see FIG. 6C). After the liquid-repellent treatment in Step S22, the bottoms (photothermal conversion layer 16) of the target sites 9 are lyophilic whereas the surface of the partition 17 is liquid-repellent, so that the functional liquids 41 can be uniformly wet over the entire bottoms of the target sites 9.

The functional liquids 41 ejected into the target sites 9 in Substep A contain the light-emitting materials that emit light of the colors of the light-emitting elements 20 to which the target sites 9 correspond. That is, the functional liquids 41 provided in the target sites 9 contain the light-emitting materials of the same colors as the light-emitting elements 20 opposite which the target sites 9 are to be positioned when the donor substrate 14 is stacked on the acceptor substrate 10. Specifically, the functional liquids 41R, 41G, and 41B are provided in the target sites 9 to be positioned opposite the light-emitting elements 20R, 20G, and 20B, respectively.

Substep B will then be described. After Substep A, the solvent is removed from the functional liquids 41 ejected into the target sites 9 by heating the donor substrate 14, for example, in drying equipment. This solidifies the light-emitting materials contained in the functional liquids 41 to form the light-emitting functional layers 40 containing the light-emitting materials (see FIG. 6D). To extend the emission life of the light-emitting functional layers 40, preferably, the donor substrate 14 is heated in an inert atmosphere, although it may be dried in air.

As for the order of Substep A and B, they may be performed for each of the functional liquids 41R, 41G, and 41B to form the light-emitting functional layers 40R, 40G, and 40B sequentially one by one. Alternatively, all the functional liquids 41R, 41G, and 41B may be ejected in Substep A before the light-emitting functional layers 40R, 40G, and 40B are formed simultaneously in Substep B.

In Step S23, the light-emitting functional layers 40R, 40G, and 40B are formed in the target sites 9 to be positioned opposite the light-emitting elements 20R, 20G, and 2DB, respectively, when the donor substrate 14 is stacked on the acceptor substrate 10 in Step S14 later. That is, the light-emitting functional layers 40R, 40G, and 40B formed on the donor substrate 14 and the light-emitting elements 20 on the acceptor substrate 10 have a mirror-image relationship, including their corresponding colors, so that the colors of the light-emitting functional layers 40 formed in the target sites 9 correspond to those of the light-emitting elements 20 after the stacking.

After Steps S21 to S23 above, the donor substrate 14 is prepared. Either Steps S11 to S13 or Steps S21 to S23 may be performed first, or both may be performed in parallel.

In Step S14, the light-emitting functional layers 40 formed on the donor substrate 14 are transferred onto the acceptor substrate 10 (see FIGS. 7A and 7B). Step S14 includes a substep of disposing the donor substrate 14 such that the light-emitting functional layers 40, corresponding to organic functional layers, are positioned opposite the acceptor substrate 10 (Substep C) and a substep of transferring the light-emitting functional layers 40 onto the acceptor substrate 10 by heating the light-emitting functional layers 40 under a reduced pressure with the donor substrate 14 disposed opposite the acceptor substrate 10 (Substep D).

Of these, in Substep C, the donor substrate 14 is stacked on the acceptor substrate 10 such that the light-emitting functional layers 40R, 40G, and 40B on the donor substrate 14 are positioned opposite the regions of the acceptor substrate 10 corresponding to the light-emitting elements 20R, 20G, and 20B, respectively (see FIG. 7A), in other words, in Substep C, the donor substrate 14 is disposed such that the target sites 9 overlap the corresponding light-emitting elements 20 in plan view. The partition 17 on the donor substrate 14 and the partition 77 on the acceptor substrate 10 (and the hole-injecting layer 53 formed thereon) function as spacers to prevent foreign matter from reaching the regions of the acceptor substrate 10 corresponding to the light-emitting elements 20.

In Substep D, the acceptor substrate 10 and the donor substrate 14 are placed under a reduced pressure (for example, at 10⁻³ Pa or less), and the backside of the donor substrate 14 (the side facing away from the light-emitting functional layers 40) is irradiated with infrared laser light L as radiant rays (see FIG. 7A). This sublimates the light-emitting functional layers 40, so that they are transferred from the donor substrate 14 onto the acceptor substrate 10 through vapor deposition (see FIG. 7B). The infrared laser light L also irradiates the photothermal conversion layer 16, which is disposed at the bottoms of the target sites 9 in which the light-emitting functional layers 40 have been formed. The photothermal conversion layer 16 efficiently converts the irradiation energy of the infrared laser light L into heat, so that the light-emitting functional layers 40 can more readily be heated to their sublimation temperature.

FIG. 8 is a perspective view showing the irradiation with the infrared laser light L in Step D. In this embodiment, the infrared laser light L may be applied over a wide area on the donor substrate 14 at one time; it does not have to be focused or scanned on the individual light-emitting elements 20. As shown in FIG. 8, for example, the infrared laser light L may be focused into a line and scanned relative to the donor substrate 14 because the light-emitting functional layers 40 have been formed on the donor substrate 14 such that they have a mirror-image relationship in arrangement with the light-emitting elements 20R, 20G, and 20B. This simplifies the optical system of the production apparatus used and reduces process time.

The type of radiant rays used in Substep D is not limited to the infrared laser light L; it may be, for example, incoherent infrared light. The radiant rays used may be of any type that can raise the temperature on the donor substrate 14 to at least the sublimation temperature of the light-emitting functional layers 40 to be transferred.

In Step S15, the electron-injecting layer 54, the cathode 55, and the sealing layer 59 are formed over substantially the entire surface of the acceptor substrate 10 so as to cover the light-emitting functional layers 40 (see FIG. 7C). Step S15 can be performed by various film-forming processes including spin coating, slit coating, and vapor deposition.

In Step S16, the counter substrate 11 is bonded to the sealing layer 59 with the adhesive layer 12 (see FIG. 7D), After the above process, the organic EL device 1 is completed. The used donor substrate 14 can be recycled by cleaning the target sites 9 with an organic solvent. For recycling, the above process may be started from the lyophilic treatment (oxygen plasma treatment) and liquid-repellent treatment (CF₄ plasma treatment) of the target sites 9.

With the method for producing the organic EL device 1 according to this embodiment, the light-emitting functional layers 40 of different colors can be simultaneously transferred from the single donor substrate 14 by providing the light-emitting functional layers 40 at the positions corresponding to the light-emitting elements 20 on the donor substrate 14 in advance, so that the process time can be reduced. In addition, the light-emitting functional layers 40 are formed on the donor substrate 14 by an atmospheric process (i.e., droplet ejection), so that the process time can be reduced as compared with known methods requiring a reduced-pressure process such as vapor deposition. In addition, the functional liquids 41 are provided only at necessary positions on the donor substrate 14 in necessary amounts by droplet ejection. This method can dramatically improve the utilization efficiency of materials as compared with known methods in which a light-emitting functional layer formed over the entire surface of a donor substrate is partially transferred, thus reducing costs. In addition, even if the functional liquids 41 ejected onto the donor substrate 14 contain impurities, the impurity concentration of the light-emitting functional layers 40 can be reduced after the step of transferring the light-emitting functional layers 40 through vapor deposition. That is, the above method enjoys both the advantages of droplet ejection in patterning and the advantage of sublimation purification through vapor deposition by heating, thus enabling the production of the reliable organic EL device 1 at low cost.

### Second Embodiment

Next, a method for producing the organic EL device 1 according to a second embodiment will be described. The organic EL device 1 according to this embodiment has the same structure as that according to the first embodiment. The method for producing the organic EL device 1 according to this embodiment differs from that of the first embodiment only in part, the remaining process being identical. The following description will therefore focus on the differences from the method of the first embodiment.

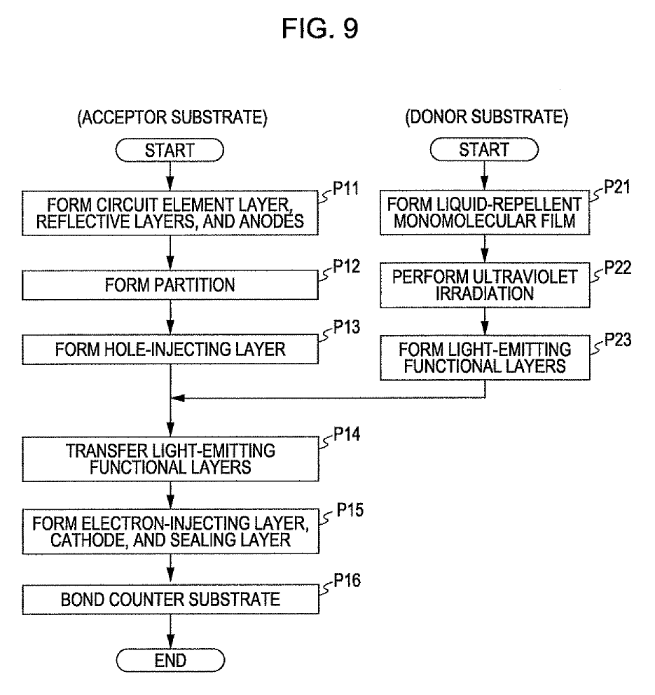

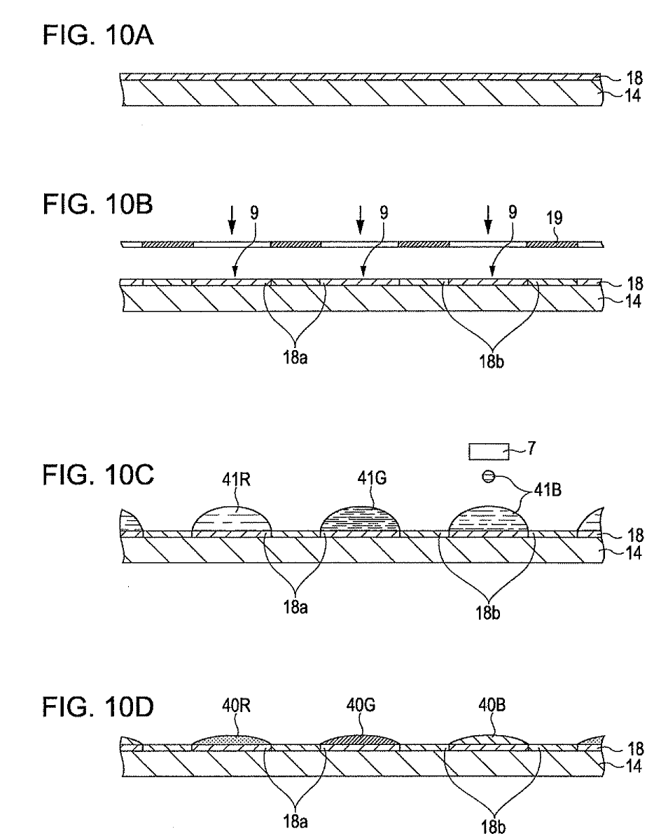

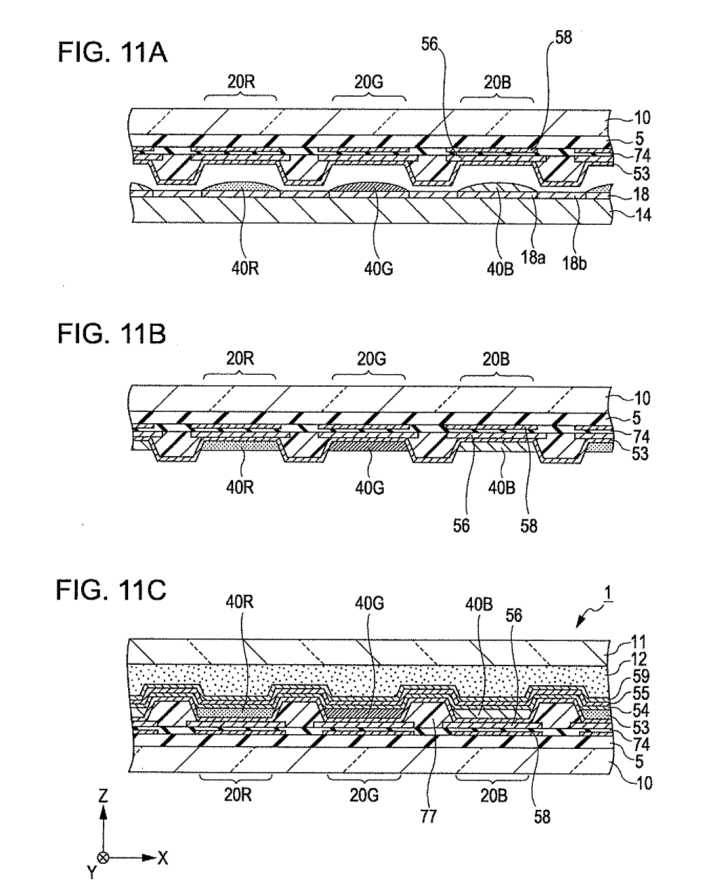

FIG. 9 is a flowchart of the method for producing the organic EL device 1 according to the second embodiment. FIGS. 10A to 10D are sectional views illustrating Steps P21 to P23 in FIG. 9. FIGS. 11A to 11C are sectional views illustrating Steps P14 to P16 in FIG. 9. The method for producing the organic EL device 1 will now be described along the flowchart of FIG. 9.

Steps P11 to P13 are identical to Steps S11 to S13 in the first embodiment.

Step P14 is preceded by Steps P21 to P23 because the donor substrate 14 to be produced in Step P23 is used in Step P14.

In Step P21, a liquid-repellent monomolecular film 18 is formed over substantially the entire surface of the donor substrate 14 (see FIG. 10A). The liquid-repellent monomolecular film 18 may be, for example, a fluoroalkylsilane monomolecular film formed by plasma-enhanced CVD. The donor substrate 14 is formed of a metal and has a heating wire embedded therein. The heating wire heats the donor substrate 14 when supplied with current.

In Step P22, part of the liquid-repellent monomolecular film 18 is irradiated with ultraviolet rays through a mask 19 (see FIG. 103). The ultraviolet rays denature the irradiated regions of the liquid-repellent monomolecular film 18 to make them lyophilic. These regions are hereinafter also referred to as lyophilic regions 18a, whereas the region remaining liquid-repellent is hereinafter also referred to as a liquid-repellent region 18b.

More specifically, the mask 19 is a quartz substrate on which a light-shielding member with an opening pattern is disposed. The mask 19 allows only ultraviolet rays entering openings of the light-shielding member to irradiate the donor substrate 14, and its irradiated regions become lyophilic. The openings of the light-shielding member are located over regions where the light-emitting functional layers 40 are to be formed by ejecting the functional liquids 41 in the next step, namely, Step P23. The lyophilic regions 18a can thus be formed in the regions where the light-emitting functional layers 40 are to be formed on the donor substrate 14, whereas the liquid-repellent region 18b can be left in the other region. In this embodiment, the lyophilic regions 18a, surrounded by the liquid-repellent region 18b, correspond to the target sites 9 on the surface of the donor substrate 14. The regions where the light-emitting functional layers 40 are to be formed are the regions to be positioned opposite the light-emitting elements 20 on the acceptor substrate 10 when the donor substrate 14 is stacked on the acceptor substrate 10 in Step P14 later. In this embodiment, as in the first embodiment, the target sites 9 are arranged such that they have a mirror-image relationship in arrangement with the light-emitting elements 20 on the acceptor substrate 10.

In Step P23, the light-emitting functional layers 40 are formed in the target sites 9 by droplet ejection (see FIGS. 10C and 10D). Step P23 includes a substep of ejecting the functional liquids 41, which contain light-emitting materials as organic functional materials, into the target sites 9 on the donor substrate 14 (Substep A) and a substep of removing the solvent from the functional liquids 41 to form the light-emitting functional layers 40 in the target sites 9 as organic functional layers containing light-emitting materials (Substep B).

Of these, Substep A will be described. First, the functional liquids 41 are prepared, containing organic functional materials. The compositions of the functional liquids 41 and the method for preparing them are the same as those in the first embodiment. The functional liquids 41 thus prepared are then ejected from the droplet-ejecting head 7 of the droplet-ejecting apparatus into the target sites 9 (see FIG. 10C). After the ultraviolet irradiation in Step P22, the target sites 9 are lyophilic (lyophilic regions 18a) whereas the region surrounding the target sites 9 is liquid-repellent (liquid-repellent region 18b), so that the functional liquids 41, when ejected into the target sites 9, are uniformly wet over the entire target sites 9 without spilling out of the target sites 9.

In this embodiment, the functional liquids 41 ejected into the target sites 9 in Substep A contain light-emitting materials that emit light of the colors of the light-emitting elements 20 to which the target sites 9 correspond. That is, the functional liquids 41 provided in the target sites 9 contain light-emitting materials of the same colors as the light-emitting elements 20 opposite which the target sites 9 are to be positioned when the donor substrate 14 is stacked on the acceptor substrate 10. Specifically, the functional liquids 41R, 41G, and 41B are provided in the target sites 9 to be positioned opposite the light-emitting elements 20R, 20G, and 20B, respectively.

Substep B will then be described. After Substep A, the solvent is removed from the functional liquids 41 ejected into the target sites 9 by heating the donor substrate 14 with a weak current supplied to the heating wire in the donor substrate 14. This solidifies the light-emitting materials contained in the functional liquids 41 to form the light-emitting functional layers 40 containing the light-emitting materials (see FIG. 10D). The heating temperature of the donor substrate 14 should be around the temperature at which the solvent vaporizes so that the heating temperature does not reach the sublimation temperature of the resultant light-emitting functional layers 40. To extend the emission life of the light-emitting functional layers 40, preferably, Substep B is performed in an inert atmosphere, although it may be performed in air. Alternatively, Substep B may be performed by heating the donor substrate 14, for example, in drying equipment.

As for the order of Substep A and B, they may be performed for each of the functional liquids 41R, 41G, and 41B to form the light-emitting functional layers 40R, 40G, and 40B sequentially one by one. Alternatively, as shown in FIGS. 10C and 10D, all the functional liquids 41R, 41G, and 41B may be ejected in Substep A before the light-emitting functional layers 40R, 40G, and 40B are formed simultaneously in Substep B.

After Step P21 to P23 above, the donor substrate 14 is prepared. Either Steps P11 to P13 or Steps P21 to P23 may be performed first, or both may be performed in parallel.

In Step P14, the light-emitting functional layers 40 formed on the donor substrate 14 are transferred onto the acceptor substrate 10 (see FIGS. 11A and 11B). Step P14 includes a substep of disposing the donor substrate 14 such that the light-emitting functional layers 40, serving as organic functional layers, are positioned opposite the acceptor substrate 10 (Substep C) and a substep of transferring the light-emitting functional layers 40 onto the acceptor substrate 10 by heating the light-emitting functional layers 40 under a reduced pressure with the donor substrate 14 disposed opposite the acceptor substrate 10 (Substep D).

of these, in Substep C, the donor substrate 14 is stacked on the acceptor substrate 10 such that the light-emitting functional layers 40R, 40G, and 40B on the donor substrate 14 are positioned opposite the regions of the acceptor substrate 10 corresponding to the light-emitting elements 20R, 20G, and 20B, respectively (see FIG. 11A). In other words, in Substep C, the donor substrate 14 is disposed such that the target sites 9 overlap the corresponding light-emitting elements 20 in plan view.

In Substep D, the acceptor substrate 10 and the donor substrate 14 are placed under a reduced pressure (for example, at 10⁻³ Pa or less), and the donor substrate 14 is heated by supplying current to the heating wire in the donor substrate 14. This sublimates the light-emitting functional layers 40, so that they are transferred from the donor substrate 14 onto the acceptor substrate 10 through vapor deposition (see FIG. 11B). The heating temperature of the donor substrate 14 in Substep D is at least the sublimation temperature of the light-emitting functional layers 40, for example, 300° C. or more.

Steps P15 and P16 are identical to Steps S15 and S16 in the first embodiment. After the above process, the organic EL device 1 is completed (see FIG. 11C). The used donor substrate 14 can be recycled. For recycling, the above process may be started from the ejection of the functional liquids 41 after cleaning the target sites 9 with an organic solvent or from the formation of the liquid-repellent monomolecular film 18 after removing the liquid-repellent monomolecular film 18 by exposing it to ultraviolet ozone while heating the donor substrate 14.

The above method for producing the organic EL device 1 according to this embodiment provides not only the same advantages as the method according to the first embodiment, but also the following extra advantage: the method according to this embodiment, in which the light-emitting functional layers 40 are transferred by directly heating the donor substrate 14 without using an infrared laser, eliminates the need for an infrared laser system, thus simplifying the configuration of the production apparatus used. The light-emitting functional layers 40 can be transferred simply by heating the donor substrate 14 because they have been provided at the positions corresponding to the light-emitting elements 20 on the donor substrate 14 by droplet ejection.

Electronic Apparatus

The above organic EL device 1 can be mounted on, for example, an electronic apparatus such as a cellular phone. FIG. 13 is a perspective view of a cellular phone 200 serving as an electronic apparatus. The cellular phone 200 has a display unit 210 and operating buttons 220. The display unit 210, incorporating the organic EL device 1, provides a high-quality display without unevenness or appearance of graininess for various information such as information input by the operating buttons 220 and incoming information.

In addition to the above cellular phone 200, the organic EL device 1 can be used for various electronic apparatuses such as mobile computers, television sets, digital cameras, digital video cameras, car-mounted equipment, and audio equipment.

Various modifications can be added to the above embodiments, including the following modifications.

First Modification

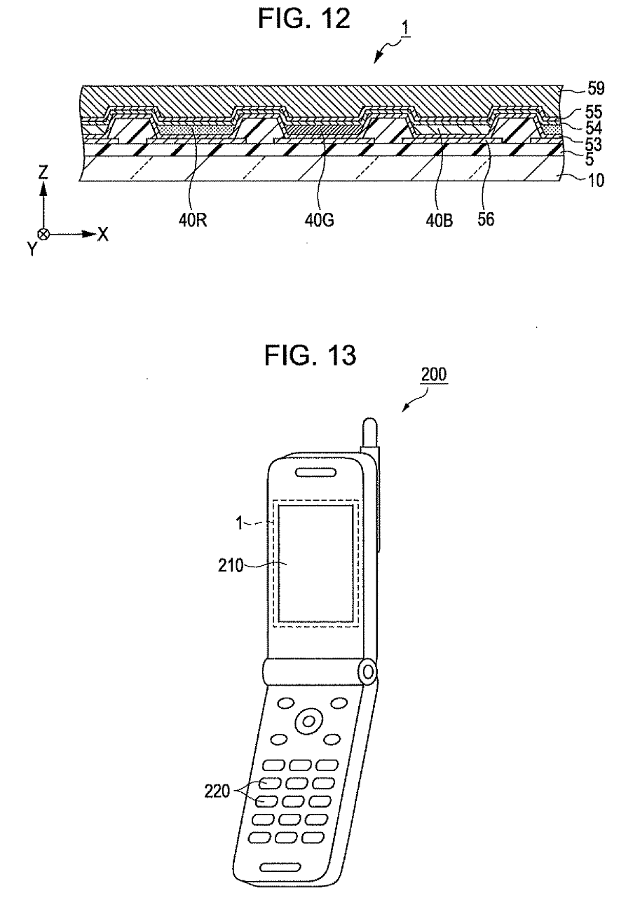

The organic EL device 1, which has a top-emission structure in the above embodiments, may instead have a bottom-emission structure. FIG. 12 is a schematic sectional view of a bottom-emission organic EL device 1. This organic EL device 1 differs from the top-emission organic EL device 1 (see FIG. 7D) in that it does not include the reflective layers 58 and the third interlayer insulating layer 74, that the cathode 55 is made thicker so that it functions as a reflective film, and that the sealing layer 59 is used for sealing instead of bonding the counter substrate 11. In the bottom-emission structure, as in the top-emission structure, the counter substrate 11 may be bonded to the sealing layer 59 as a sealing substrate. According to this structure, some of light emitted from the light-emitting functional layers 40 exits from the acceptor substrate 10 directly, while other light exits from the acceptor substrate 10 after being reflected from the cathode 55. For the bottom-emission organic EL device 1, as in the case of the top-emission organic EL device 1, the light-emitting functional layers 40 can be formed by the transfer from the donor substrate 14 through vapor deposition.

Second Modification

Although the functional liquids 41 contain light-emitting materials as organic functional materials in the above embodiments, the invention is not limited thereto. The functional liquids 41 ejected into the target sites 9 on the donor substrate 14 may contain different organic functional materials for the individual colors of the light-emitting elements 20 to which the target sites 9 correspond. The organic functional materials contained in the functional liquids 41 may be, for example, hole-injecting materials, hole-transporting materials, electron-injecting materials, or electron-transporting materials, and the corresponding organic functional layers may be, for example, hole-injecting layers, hole-transporting layers, electron-injecting layers, or electron-transporting layers. Different organic functional materials and organic functional layers can thus be provided for the individual colors of the light-emitting elements 20 to optimize the characteristics of the light-emitting elements 20 of the individual colors.

Third Modification

Although the organic EL device 1 according to the above embodiments includes the hole-injecting layer 53 on the side of the light-emitting functional layers 40 facing the acceptor substrate 10 and the electron-injecting layer 54 on the side facing the sealing layer 59, the structure may be changed depending on the arrangement of electrodes. Specifically, for a structure in which the cathode 55 is disposed on the side of the light-emitting functional layers facing the acceptor substrate 10 and the anodes 56 are disposed on the side facing the sealing layer 59, the electron-injecting layer 54 may be disposed on the side of the light-emitting functional layers 40 facing the cathode 55 and the hole-injecting layer 53 may be disposed on the side facing the anodes 56.

The entire disclosure of Japanese Patent Application No. 2008-027300, filed Feb. 7, 2008 is expressly incorporated by reference herein.

What is claimed is:

1. A method for producing a light-emitting device, comprising:
ejecting functional liquids containing organic functional materials into target sites on a donor substrate;
removing a solvent from the functional liquids to form organic functional layers containing the organic functional materials in the target sites;
disposing the donor substrate such that the organic functional layers are positioned opposite an acceptor substrate; and
transferring the organic functional layers onto the acceptor substrate by heating the organic functional layers under a reduced pressure with the donor substrate disposed opposite the acceptor substrate.

2. The method for producing the light-emitting device according to claim 1, wherein the organic functional layers are transferred by irradiating the side of the donor substrate facing away from the organic functional layers with radiant rays.

3. The method for producing the light-emitting device according to claim 2, wherein
the bottoms of the target sites are defined by a photothermal conversion layer formed on a surface of the donor substrate; and
the organic functional layers are transferred by irradiating the photothermal conversion layer with the radiant rays.

4. The method for producing the light-emitting device according to claim 1, wherein the organic functional layers are transferred by heating the donor substrate.

5. The method for producing the light-emitting device according to claim 1, wherein the target sites are recesses whose sides are defined by a partition formed on the donor substrate.

6. The method for producing the light-emitting device according to claim 1, wherein
a surface of the donor substrate has a liquid-repellent region and lyophilic regions surrounded by the liquid-repellent region; and
the target sites are the lyophilic regions on the surface of the donor substrate.

7. The method for producing the light-emitting device according to claim 1, wherein
the light-emitting device includes light-emitting elements that each emit light of one of different colors;
the target sites are arranged so as to have a mirror-image relationship with the light-emitting elements; and
the donor substrate is disposed such that the target sites overlap the corresponding light-emitting elements in plan view.

8. The method for producing the light-emitting device according to claim 7, wherein
the light-emitting elements each correspond to one of the different colors; and
the functional liquids ejected into the target sites contain different organic functional materials for the individual colors of the light-emitting elements to which the target sites correspond.

9. The method for producing the light-emitting device according to claim 7, wherein
the light-emitting elements each correspond to one of the different colors; and
the functional liquids ejected into the target sites contain organic functional materials that emit light of the colors of the light-emitting elements to which the target sites correspond.
